(19) United States
(12) Patent Application Publication
(10) Pub. No.: US 2026/0206503 A1
(43) Pub. Date: Jul. 16, 2026

(54) Plasma Treatment for Dielectric Layers

(71) Applicant: TEXAS INSTRUMENTS INCORPORATED, Dallas, TX (US)

(72) Inventors: Alex Gibbs, Salt Lake City, UT (US); Saiful Islam, Lehi, UT (US); Ryan Gebhardt, Lehi, UT (US)

(21) Appl. No.: 19/067,332

(22) Filed: Feb. 28, 2025

Related U.S. Application Data
(60) Provisional application No. 63/744,055, filed on Jan. 10, 2025.

(51) Int. Cl. H10P 14/60; H10P 14/692

(52) U.S. Cl. CPC H10P 14/6529; H10P 14/6927

(57) ABSTRACT

A method is disclosed herein. The method includes forming a material layer over a dielectric layer, performing a treatment process, forming a treated material layer as a result of performing the treatment process, and forming a photoresist layer over the treated material layer. The treated material layer has an increased oxygen concentration compared to the material layer.

### CROSS-REFERENCE TO RELATED APPLICATIONS

This application claims priority to U.S. Provisional Patent Application No. 63/744,055, entitled “N2O treatment for SiON layer”, filed January 10, 2025, which is hereby incorporated by reference in its entirety.

### BACKGROUND

Integrated circuits may include interconnect structures having conductive features, such as metal lines and vias, that connect different semiconductor components to each other within an integrated circuit. In some integrated circuits, the conductive features may be formed in a dielectric layer. During manufacturing of the conductive features, a patterned photoresist layer may be formed on the dielectric layer to provide a mask for forming an opening in which the conductive feature may be formed. In some integrated circuits, these conductive features may form an interface with various materials including dielectric materials and other conductive features. However, inadequate adhesion of the patterned photoresist layer to the dielectric layer may affect the formation of the opening for the conductive feature.

### SUMMARY

A method is disclosed herein. The method includes forming a material layer over a dielectric layer, performing a treatment process, forming a treated material layer as a result of performing the treatment process, and forming a photoresist layer over the treated material layer. The treated material layer has an increased oxygen concentration compared to the material layer.

Also disclosed herein is a method. The method includes forming a material layer over a substrate. The material layer includes oxygen and nitrogen. The method further includes performing an N₂O treatment process to the material layer to form a treated material layer. The method further includes forming a patterned photoresist layer over the treated material layer.

Also disclosed herein is a method. The method includes forming a silicon oxynitride (SiON) layer over a hard mask. The SiON layer has a first oxygen concentration. The method further includes performing a treatment process and forming a treated SiON layer as a result of the performing the treatment process. The SiON layer having a second oxygen concentration that is greater than the first oxygen concentration. The method further includes forming a patterned photoresist layer on the treated SiON layer.

The foregoing features and elements may be combined in any combination, without exclusivity, unless expressly indicated herein otherwise. These features and elements as well as the operation of the disclosed examples will become more apparent in light of the following description and accompanying drawings.

### BRIEF DESCRIPTION OF THE DRAWINGS

Reference will now be made to the accompanying drawings, which are not necessarily drawn to scale. While the drawings illustrate various examples employing the principles described herein, the drawings do not limit the scope of the claims.

FIG. 1 illustrates a flow chart for a method of forming a semiconductor device, in accordance with various examples.

FIGS. 2A, 2B, 2C, 2D, and 2E, illustrate cross-section views of a semiconductor device, in accordance with the process of FIG. 1 and the various examples associated therewith.

FIG. 3 illustrates a flow chart for a method of forming a semiconductor device, in accordance with various examples.

FIGS. 4A, 4B, 4C, 4D, 4E, 4F, and FIG. 4G illustrate cross-section views of a semiconductor device, in accordance with the process of FIG. 3 and the various examples associated therewith.

FIGS. 5A, 5B, and 5C, illustrate charts of element concentrations in semiconductor devices formed in accordance with the processes of FIG. 1 or FIG. 3 and the various examples associated therewith.

### DETAILED DESCRIPTION

The following detailed description is presented for purposes of illustration and not of limitation. Benefits, advantages, and/or solutions to problems may be described with reference to various examples. The detailed description makes use of the various examples and refers to the accompanying drawings which illustrate the various examples described herein. The drawings, descriptions, and examples are described in sufficient detail to practice the disclosure. It is understood that connecting lines shown in the various drawings are intended to represent example functional relationships and/or physical couplings between various elements, but that other relationships and/or couplings are possible while remaining within the scope of the present disclosure. It will further be appreciated that the various drawings may not be drawn to scale in order to simplify and clarify the detailed description herein. Furthermore, it is understood that the descriptions and examples contained herein may permit the practice other examples using logical, chemical, and/or mechanical changes without departing from the spirit and scope of this disclosure. For example, the steps recited in method and process descriptions may be executed in a different order, additional process steps may be added, and/or process steps may be removed while remaining within the scope of the present disclosure.

Any reference to singular items and/or examples includes plural items and/or examples and any reference to more than one item and/or example may include a singular item and/or example. Similarly, references to “a”, “an”, or “the” may include one or more of the referenced items, unless stated otherwise. Any reference to connected, coupled, fixed, attached, or the similar words and/or phrases may include partial, full, temporary, removable, permanent, or the other connection options. Any reference to contact, or similar phrase, may include minimal contact or reduced contact. All ranges used herein may include both the upper and lower values of the ranges, including ratio limits, that are disclosed herein. Stated values may include at least the variation that is expected within the field in which the present disclosure is practiced and as would be understood and accepted to include values that are within 10% of a stated value. Similarly, the use of “approximately”, “about”, “substantially” or other similar term represents an amount that is close to the stated value and that may still achieve the stated, or desired, result and/or perform the stated, or desired, function and may refer to an amount that is within 10% of the stated value.

The accompanying drawings, and detailed description of the drawings, include reference numerals that may be repeated across multiple examples. The repetition of reference numerals is intended simplicity and clarity of description and is not intended to form or dictate a relationship between different examples described herein. The examples and descriptions provided herein are intended to be illustrative and not limiting beyond the scope of the claims. The use of terms such as “on” and “over” may indicate that a first feature is formed directly contacting a second feature or may indicate a relationship of the first feature and the second feature without direct contact between the two, such as additional features being formed between the two. For example, “on” may be used to indicate direct contact between the two and “over” may be used to indicate one or more intervening layers between the two.

Spatially relative terms such as, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of discussion herein and are not intended to limit the orientation of the various components, systems, apparatuses, devices, or other features. It is therefore understood and appreciated that the use of the spatially relative terms to practice this disclosure in different orientations remains within the scope of the present disclosure.

The present disclosure relates generally, but not exclusively, to semiconductor processing for improving adhesion between a photoresist layer formed directly on an underlying material layer. In various examples, poor adhesion between the photoresist layer and the underlying material layer may result in a portion of the photoresist material falling over, or toppling, which may affect trench formation and may disrupt the formation of metal lines and vias in subsequent processes. Specifically, toppled photoresist can block trench etch processes which may disrupt the formation of metal lines and vias. In various examples, the disrupted metal line and via formation may result in degraded and/or unusable components.

To address these issues, disclosed herein are methods for performing a treatment process to improve adhesion between an underlying material layer and the photoresist layer formed thereover. In various examples, an oxygen-based (e.g., nitrous oxide (N₂O)) plasma treatment may be performed to improve the adhesion between the underlying material layer (e.g., dielectric layer) and the photoresist layer. In various examples, the improved adhesion may result in a reduction, or prevention, of photoresist toppling. Reducing photoresist toppling may lead to improved trench formation and, as a result, a reduction in manufacturing defects. In some examples, the disclosed methods may be used with semiconductor manufacturing processes such as trench and/or via formation processes and subsequently filling of the trench and/or via with one or more material layers (e.g., conductive and/or dielectric materials). For example, the disclosed methods may be used as part of a dual damascene process that forms a trench and a via in a dielectric layer that are subsequently filled with conductive material(s).

The methods disclosed herein describe forming a dielectric layer (e.g., anti-reflective coating layer) and performing a treatment process (e.g., surface treatment, plasma treatment, N₂O treatment process) on the dielectric layer to modify the properties of the dielectric layer. Adhesion of a subsequently formed photoresist layer over the dielectric layer is improved as a result of the modified properties of the treated dielectric layer. Specifically, the methods disclosed herein are directed to a chemical vapor deposition (CVD) process for forming the dielectric layer that may include an in-situ plasma treatment (e.g., plasma enhanced CVD (PECVD) process) performed on the dielectric layer. In various examples, the CVD process may form a silicon oxynitride (SiON) layer and the in-situ plasma treatment may include a treatment process using an oxygen-based gas (e.g., N₂O). In some examples, the formation of the dielectric layer and the in-situ plasma treatment are performed using PECVD processes. In various examples, the oxygen (O₂) concentration in the dielectric layer increases as a result of the treatment process. In various examples, as a result of the treatment process, the oxygen concentration increase may occur at a surface of the dielectric layer where the photoresist layer is subsequently formed thereover. The treatment process may condition the dielectric layer, in various examples, to improve adhesion between the dielectric layer and the subsequently formed photoresist layer which mitigates toppling of the photoresist layer.

For example, the treatment process may minimize dangling bonds (e.g., dangling Si bonds) in the treated dielectric layer. As used herein, dangling bonds describe molecules (e.g., Si) that have one or more open connections, or termination points, that are not bonded to another molecule (e.g., O₂, N₂, etc.). Open connections, or dangling bonds, may absorb, or capture, moisture (e.g., from the ambient, from the photoresist layer) which may degrade adhesion between the photoresist layer and the dielectric layer. Terminating the dangling bonds by bonding oxygen to the dangling Si bonds during the treatment process reduces the moisture absorption rate of the treated dielectric layer as compared to the dielectric layer before treatment. In various examples, as a result of the CVD process and the treatment process, there may be no intervening layers between the treated dielectric layer and the photoresist layer.

Accordingly, the treatment process described herein tends to reduce toppling of a patterned photoresist layer that is formed over a treated dielectric layer. Additionally, in various examples, the treatment process is cost and cycle time neutral. In other words, the treatment process does not increase the cost of, or manufacture time for, components that utilize the methods disclosed herein. The cost and time neutrality are attributable, at least in part, to the treatment process being performed in-situ and utilizing resources already present for the CVD processes used to form the dielectric layer (e.g., N₂O, He, etc.). This method may be preferable to alternative processes that include a bottom anti-reflective coating (BARC), a multi-layered resist (MLR), or other material layer between the dielectric layer and the photoresist layer. As described herein, the treatment process allows the photoresist to be formed directly on the dielectric layer with sufficient adhesion to reduce, or prevent, toppling the photoresist after patterning.

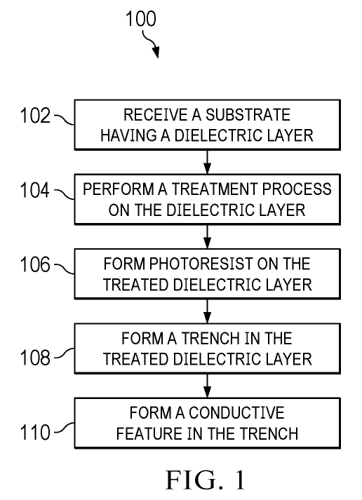

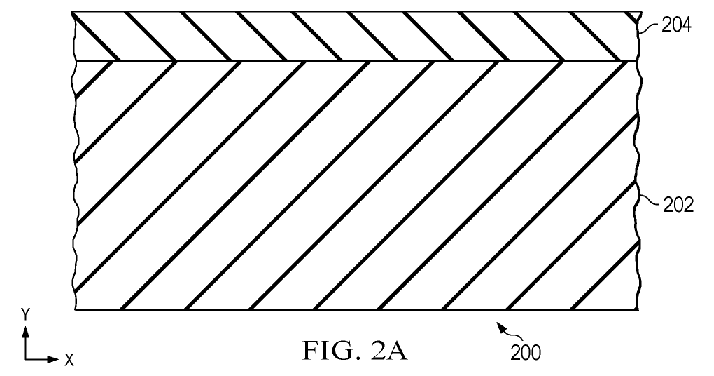

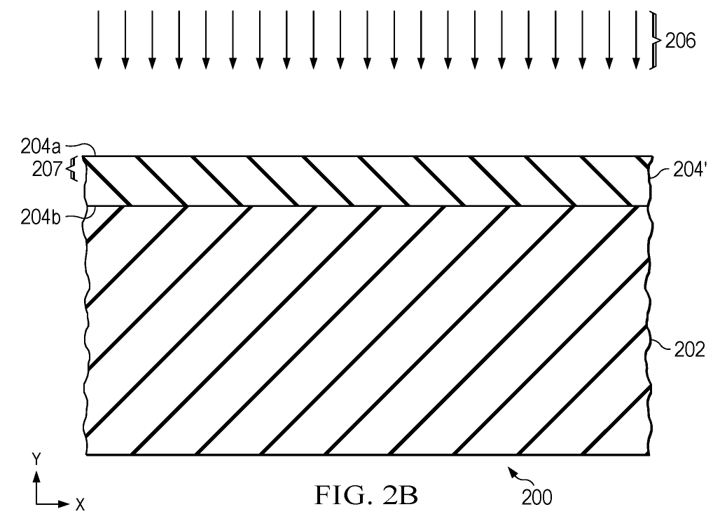

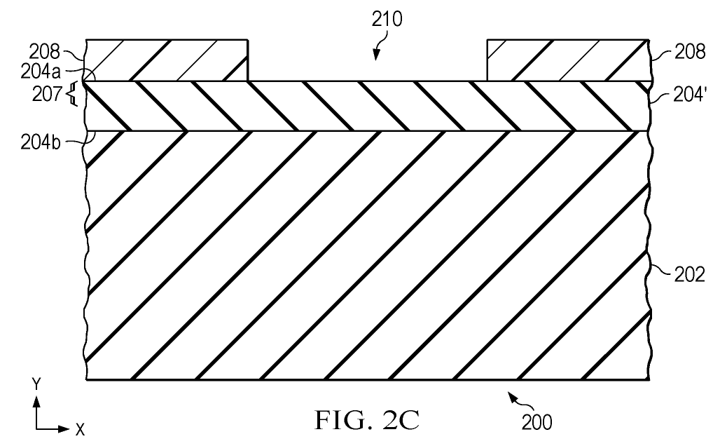

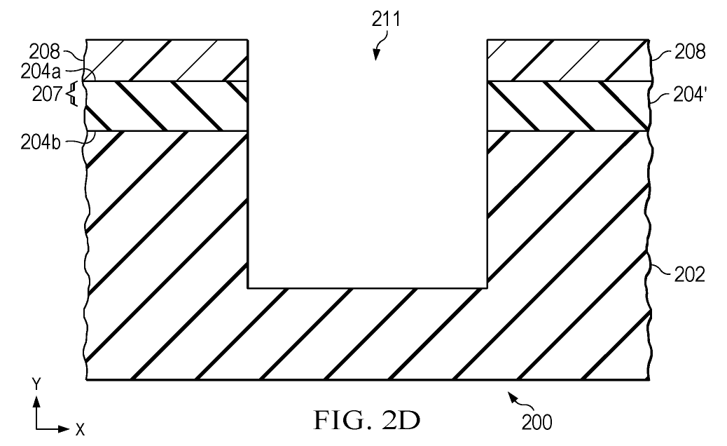

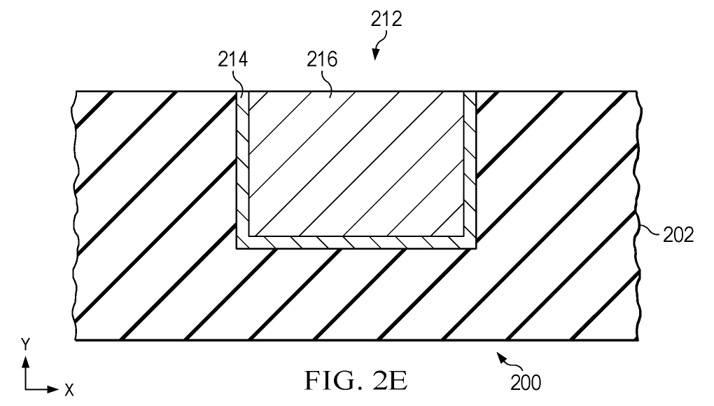

Referring now to FIG. 1, a flow diagram of a method 100 for forming a conductive feature in a semiconductor device (e.g., a field effect transistor (FET)) is illustrated in accordance with various examples of the present disclosure. In various examples, method 100 may be used to form a treated dielectric layer (e.g., anti-reflective coating (ARC) layer) that improves the adhesion of a patterned photoresist layer to the treated dielectric layer. The improved adhesion of the patterned photoresist layer tends to reduce, or prevent, toppling of a portion of the patterned photoresist layer and thereby improve formation of subsequently formed conductive features in the semiconductor device. Additional processes can be provided before, during, and after method 100. As discussed below, method 100 is described with reference to FIGS. 2A-2E.

In that regard, FIGS. 2A-2E are diagrammatic cross-sectional views of a device 200 at various stages of fabrication (such as those associated with method 100 of FIG. 1) according to various aspects of the present disclosure. In various examples, device 200 may be part of a metal structure of a transistor (e.g., an interconnect structure), a FET, a metal oxide semiconductor FET (MOSFET), a bipolar junction transistor (BJT), other semiconductor components, or the like. Additional features can be added to device 200, and some features described below can be replaced, modified, or eliminated in other examples of device 200.

At step 102 of FIG. 1, a substrate having a dielectric layer is received. As shown in FIG. 2A, device 200 includes a first dielectric layer 202 and a second dielectric layer 204 formed over first dielectric layer 202. Device 200 may be considered part of an interconnect structure where first dielectric layer 202 may be part of an interlayer dielectric layer and second dielectric layer 204 may include an anti-reflective coating (ARC) layer formed over the interlayer dielectric layer. In various examples, first dielectric layer 202 may include one or more layers. In various examples, the one or more layers may include a dielectric layer, an etch stop layer, or a combination thereof. In various examples, second dielectric layer 204 may include one or more layers. In various examples, the one or more layers may include silicon oxynitride (SiON), titanium nitride (TiN), or a combination thereof. For example, second dielectric layer 204 may include an SiON layer formed over a TiN layer that is formed over another SiON layer. In another example, second dielectric layer 204 may include one or more layers of SiON.

First dielectric layer 202 may be formed over a substrate. In various examples, first dielectric layer 202 may be an interlayer dielectric layer and the substrate may be a semiconductor substrate that includes source and drain regions and various gate stacks formed over the semiconductor substrate. In various examples, the semiconductor substrate may further include one or more contacts and/or metal lines formed over the source regions, the drain regions, and/or the gate stacks. In various examples, first dielectric layer 202 layer may include silicon oxide, silicon nitride, silicon oxynitride, a silicon oxide-based material (such as a phosphosilicate glass (PSG) or a tetraethyl orthosilicate (TEOS) oxide), polytetrafluoroethylene, low-k dielectric layers, any other dielectric material, or any combination thereof.

Second dielectric layer 204 may be formed over first dielectric layer 202. As described above, second dielectric layer 204 may include one or more material layers that are formed over first dielectric layer 202. For example, second dielectric layer 204 may be a dielectric material layer that includes oxygen and/or nitrogen such as silicon dioxide, silicon nitride, silicon oxynitride, or combination thereof. In some examples, second dielectric layer 204 may include multiple layers such as an etch stop layer (e.g., SiON), a hard mask (e.g., TiN) formed over the etch stop layer, and an anti-reflective coating (e.g., SiON) formed over the hard mask. In various examples, second dielectric layer 204 may be formed using a chemical vapor deposition (CVD) process, a plasma-enhanced CVD (PECVD) process, or a combination thereof. In various examples, second dielectric layer 204 may have a thickness (e.g., in the positive y-direction) of about 200 Å to about 400 Å, and more specifically, about 250 Å to about 350 Å.

In various examples, as described above, second dielectric layer 204 may be or include SiON. In various examples, a PECVD process may be used to form SiON within second dielectric layer 204. In such examples, the PECVD process may use silane (SiH₄), nitrous oxide (N₂O), and a noble gas to form the second dielectric layer 204. In various examples, the noble gas may include or be helium (He), neon (Ne), argon (Ar), xenon (Xe), radon (Rn), or the like. In various examples, one or more of SiH₄, N₂O, and the noble gas may be present before performing the PECVD process as part of an environmental stabilization process. In various examples, the environmental stabilization process may stabilize one or more of a substrate temperature, gas flows, pressures, temperatures, etc. before performing the PECVD process.

In various examples, the PECVD process may form SiON having a first oxygen concentration, a first nitrogen concentration, a first silicon concentration, and a first hydrogen concentration. In various examples, the first oxygen concentration may be about 64% to about 68%, and more specifically, about 65% to about 67%. In various examples, the first oxygen concentration may be generally uniform throughout a thickness (e.g., along the y-axis) of the SiON layer within second dielectric layer 204. In various examples, the first nitrogen concentration may be about 5% to about 9%, and more specifically, about 6% to about 8%. In various examples, the first silicon concentration may be about 24% to about 31%, and more specifically, about 26% to about 28%.

In some examples, the PECVD process to form second dielectric layer 204 having SiON may include various flow rates for SiH₄, N₂O, and noble gases, a radio frequency (RF) power and a pressure. For example, the PECVD process may include a flow rate of SiH₄ of about 150 sccm to about 650 sccm, and more specifically, about 300 sccm to about 500 sccm. Additionally, in some examples, the PECVD process may include a flow rate of N₂O of about 300 sccm to about 1,100 sccm, and more specifically, about 500 sccm to about 900 sccm. Also, in examples where the noble gas is He, a flow rate of He during the PECVD process may be about 5,000 sccm to about 15,000 sccm, and more specifically, about 8,000 sccm to about 12,000 sccm. In addition, the PECVD process, in some examples, may use a radio frequency (RF) power of about 150 W to about 550 W, and more specifically, about 250 W to about 450 W. Furthermore, in some examples, a pressure of the PECVD process may be about 2.5 Torr to about 8.5 Torr, and more specifically, about 4.5 Torr to about 6.5 Torr.

For purposes of clarity, the below processing steps of FIGS. 2B-2D will be described in reference to second dielectric layer 204 including or being a SiON material layer. However, the processing steps below are applicable to other processes where second dielectric layer 204 may include other dielectric materials such as oxide and/or nitride material layers.

At step 104 of FIG. 1, a treatment process is performed on the dielectric layer. As shown in FIG. 2B, a treatment process 206 is performed to form a treated second dielectric layer 204’. In various examples, treatment process 206 may also be referred to as a surface treatment process, an in-situ treatment process, an N₂O treatment process, a nitrogen-containing treatment, an oxygen-containing treatment, or similar. In various examples, treatment process 206 may be performed in-situ after forming second dielectric layer 204. In other words, treatment process 206 is performed without moving device 200 to a different processing chamber and/or environment (e.g., without breaking vacuum of the environment). In other examples, treatment process 206 may be performed ex-situ after forming second dielectric layer 204. In other words, treatment process 206 is performed by moving device 200 to a different processing chamber and/or environment (e.g., breaking vacuum of the environment). In various examples, treatment process 206 includes using a PECVD process to treat second dielectric layer 204.

In various examples, treatment process 206 replaces nitrogen (N₂) and hydrogen (H₂) in treated second dielectric layer 204’ with oxygen (O₂). Additionally, treatment process 206 terminates dangling bonds (e.g., dangling Si bonds) in treated second dielectric layer 204’ with oxygen. As a result of terminating dangling bonds, the moisture absorption rate of treated second dielectric layer 204’ is less than the moisture absorption rate of second dielectric layer 204. As used herein, dangling Si bonds include Si molecules that have an open bond that is not occupied by another atom such as an oxygen, hydrogen or nitrogen atom.

After treatment process 206, treated second dielectric layer 204’ has a second oxygen concentration, a second nitrogen concentration, a second silicon concentration, and a second hydrogen concentration. Second oxygen concentration is greater than the first oxygen concentration while second nitrogen concentration, second silicon concentration, and second hydrogen concentration are less than first nitrogen concentration, first silicon concentration, and first hydrogen concentration, respectively.

In various examples, the second oxygen concentration may be about 69% to about 73%, and more specifically, about 70% to about 72%. In various examples, second nitrogen concentration may be about 1% to about 5%, and more specifically, about 2.5% to about 4.5%. In various examples, second silicon concentration may be about 22% to about 32%, and more specifically, about 24% to about 26%. In other words, treatment process 206 may increase the oxygen concentration while decreasing the nitrogen concentration and the hydrogen concentration in portions of second dielectric layer 204 to form treated second dielectric layer 204’. In various examples, the treatment process 206 (e.g., decreasing nitrogen and/or hydrogen contents) results in treated second dielectric layer 204’ being denser than at least portions of second dielectric layer 204.

In various examples, the second oxygen concentration of treated second dielectric layer 204’ may be a non-linear gradient with a top surface 204a (e.g., in the positive y-direction) of treated second dielectric layer 204’ having the highest (or higher) oxygen concentration relative to other portions of treated second dielectric layer 204’. As shown in FIG. 2B, top surface 204a, or treated surface, faces away from first dielectric layer 202 while an opposing bottom surface 204b of treated second dielectric layer 204’ faces first dielectric layer 202.

In various examples, only an upper portion 207 (e.g., in the positive y-direction) of treated second dielectric layer 204’ (e.g., thickness of about 10 Å to about 50 Å, and more specifically, about 20 Å to about 40 Å of second dielectric layer 204) may be affected by treatment process 206. As a result, in some examples, there may remain portions of treated second dielectric layer 204’ having a generally uniform oxygen concentration under (e.g., in the negative y-direction) upper portion 207 which has a higher gradient oxygen concentration. In some examples, the oxygen concentration in upper portion 207 has a linear or non-linear oxygen concentration gradient that generally increases in the positive y-direction toward top surface 204a. In some examples, a thin oxide layer is formed on top surface 204a as a result of treatment process 206.

In various examples, treatment process 206 may use nitrous oxide (N₂O), radio frequency (RF) power, and pressure to increase the oxygen (O₂) concentration (while decreasing nitrogen and/or hydrogen concentration) of treated second dielectric layer 204’. In some examples, the N₂O may breakdown easily with low RF power to provide a source of O₂ for treatment process 206. The temperature and pressure of treatment process 206 may cause the oxygen (O₂) to replace hydrogen (H₂) and/or nitrogen (N₂) bonds in the second dielectric layer 204 resulting in a higher oxygen concentration and a lower hydrogen and nitrogen concentration in treated second dielectric layer 204’. In other words, treatment process 206 reduces Si-H bonds in second dielectric layer 204 by replacing the H₂ in a portion of the Si-H bonds with oxygen. The increased oxygen concentration (in conjunction with decreased nitrogen and/or hydrogen concentrations) tends to increase the quality and robustness of treated second dielectric layer 204’ as compared to second dielectric layer 204. The improved quality improves the adhesion of subsequently formed photoresist layer (e.g., patterned photoresist layer 208 described below) to treated second dielectric layer 204’ as compared to second dielectric layer 204.

In various examples, treatment process 206 may use nitrous oxide (N₂O) and a noble gas. In various examples, the noble gas may include or be helium (He), neon (Ne), argon (Ar), xenon (Xe), radon (Rn), or the like. In various examples, one or both N₂O and the noble gas may be present from previous the PECVD process used to form second dielectric layer 204. During treatment process 206, the flow rate of N₂O may about 3,000 sccm to about 8,000 sccm, and more specifically, about 4,500 sccm to about 6,500 sccm. In examples where the noble gas is He, the flow rate of He during treatment process 206 may be about 500 sccm to about 2,500 sccm, and more specifically, about 1,000 sccm to about 2,000 sccm. Treatment process 206 may use a radio frequency (RF) power of about 250 W to about 850 W, and more specifically, about 450 W to about 650 W. The pressure of the PECVD process may be about 4 Torr to about 12 Torr, and more specifically, about 6 Torr to about 8 Torr. Treatment process 206 may performed for about 30 s to about 120 s, and more specifically, about 45 s to about 75 s.

At step 106 of FIG. 1, a photoresist is formed on the treated dielectric layer. As shown in FIG. 2C, a patterned photoresist layer 208 is formed directly on top surface 204a of treated second dielectric layer 204’. Patterned photoresist layer 208 has an opening 210 that exposes top surface 204a of treated second dielectric layer 204’. In various examples, patterned photoresist layer 208 may include a plurality of openings similar to opening 210. Patterned photoresist layer 208 may be formed, in various examples, by a photolithographic process. In various examples, patterned photoresist layer 208 may include a negative photoresist material or a positive photoresist material. Patterned photoresist layer 208 may be patterned using one or more exposure and development processes. As described below, patterned photoresist layer 208 may be used as a mask to form a trench (e.g., trench 211) in first dielectric layer 202.

Adhesion of patterned photoresist layer 208 to treated second dielectric layer 204’ is improved as a result of treatment process 206. Specifically, the adhesion may be improved as a result of the increased O₂ concentration, the reduced N₂ concentration, the reduced H₂ concentration, and/or the reduced dangling Si bonds in treated second dielectric layer 204’, including along top surface 204a, as compared to second dielectric layer 204. As shown in FIG. 2C, because of the improved adhesion of patterned photoresist layer 208 to treated second dielectric layer 204’, patterned photoresist layer 208 has not experienced any toppling issues that would affect the formation of opening 210 or the formation of subsequent trenches and/or other features formed therein.

For example, treatment process 206 may minimize (or reduce) dangling bonds (e.g., dangling Si bonds) in treated second dielectric layer 204’. Dangling bonds, may absorb, or capture, moisture (e.g., from the ambient, from a photoresist layer) which may cause toppling of a portion of the photoresist layer. Terminating the dangling bonds (e.g., reducing the number of dangling bonds) by bonding oxygen to the dangling Si bonds during treatment process 206 reduces the moisture absorption rate of treated second dielectric layer 204’. As such, treated second dielectric layer 204’ has improved adhesion properties which reduces, or prevents, toppling of patterned photoresist layer 208 during the steps of method 100. Reducing, or preventing, toppled photoresist improves the formation of conductive features (e.g., metal lines, vias, etc.) in the subsequently formed trench (e.g., trench 211) and, as a result, the quality of device 200.

At step 108 of FIG. 1, a trench is formed in the treated dielectric layer. As shown in FIG. 2D, a trench 211 is formed using patterned photoresist layer 208 as a mask. Trench 211 extends through treated second dielectric layer 204’ and into first dielectric layer 202. As shown, trench 211 is formed as intended because patterned photoresist layer 208 has not experienced any toppling issues. That is, no portion of patterned photoresist layer 208 has “toppled” over thereby blocking and/or negatively effecting the formation of trench 211 while using patterned photoresist layer 208 as a mask.

Trench 211 may be formed using one or more etching processes. For example, a first etching process may be performed to etch through treated second dielectric layer 204’ to expose first dielectric layer 202. A second etching process may then be performed to etch into first dielectric layer 202. In other examples, a single etching process may be used to etch through treated second dielectric layer 204’ and into first dielectric layer 202. In various examples, the one or more etching processes may be a wet etch process, a dry etch process, or a combination thereof. In various examples, the one or more etching processes may be tuned to remove more material from first dielectric layer 202 and/or treated second dielectric layer 204’ in a vertical direction (e.g., along the y-axis) than in a horizontal direction (e.g., along the x-axis).

After forming trench 211, patterned photoresist layer 208 and/or treated second dielectric layer 204’ may be removed using one or more processes. In various examples, the one or more processes may include a wet etch, a dry etch, a chemical mechanical polish (CMP) process, the like, or a combination thereof. In various examples, a different process may be used to remove each of patterned photoresist layer 208 and/or treated second dielectric layer 204’. In various examples, a same process may be used to remove patterned photoresist layer 208 and/or treated second dielectric layer 204’. In other examples, treated second dielectric layer 204’ may be removed during the formation of conductive feature 212 described below with respect to FIG. 2E.

At step 110 of FIG. 1, a conductive feature is formed in the trench. As shown in FIG. 2E, a conductive feature 212 is formed in trench 211. Conductive feature 212 includes a barrier layer 214 and a conductive layer 216.

Barrier layer 214 may be formed over first dielectric layer 202 and in trench 211, including along sidewalls and bottom surfaces of trench 211. In various examples, barrier layer 214 may include titanium (Ti), titanium nitride (TiN), tantalum (Ta), tantalum nitride (TaN), the like, or a combination thereof. In various examples, barrier layer 214 may be formed by a physical vapor deposition (PVD), a chemical vapor deposition (CVD) process, other suitable processing techniques, or a combination thereof.

Conductive layer 216 may formed over barrier layer 214 disposed within trench 211. Conductive layer 216 may include an overburden portion that extends above (e.g., in the positive y-direction) a top surface of first dielectric layer 202 outside of trench 211 that is subsequently removed. In various examples, conductive layer 216 may be or include a metal such as copper (Cu), tungsten (W), aluminum (Al), the like, or a combination thereof. In various examples, conductive layer 216 may be formed by an electroplating process, a physical vapor deposition (PVD), a chemical vapor deposition (CVD) process, a sputtering process, other suitable processing techniques, or a combination thereof.

In various examples, the formation of barrier layer 214 and conductive layer 216 within trench 211 may include a planarization process such as a chemical mechanical polishing (CMP) process. In some examples, as described above, treated second dielectric layer 204’ may be removed during the formation of conductive feature 212. That is, in some examples, barrier layer 214 and conductive layer 216 may be formed over treated second dielectric layer 204’ in addition to within trench 211 and then subjected to a planarization process. In such examples, the planarization process may remove portions of treated second dielectric layer 204’, barrier layer 214, and/or conductive layer 216 that are present outside of trench 211 to form conductive feature 212.

Accordingly, method 100 provides a treatment process to improve adhesion between a dielectric layer and a photoresist layer. In various examples, the dielectric layer may include oxygen and/or nitrogen (e.g., SiON), and the treatment process may include nitrous oxide (N₂O). In various examples, the treatment process may increase the oxygen concentration (while decreasing the nitrogen concentration) in at least a portion (e.g., upper surface) of the dielectric layer which improves the adhesion of the photoresist layer to the dielectric layer. The improved adhesion has the effect of reducing, or preventing, toppled photoresist during the steps of method 100. Reducing, or preventing, toppled photoresist improves the formation of conductive features (e.g., metal lines, vias, etc.) in the subsequently formed trench (e.g., trench 211) and, as a result, improves the quality of device 200.

Although process 100 has been described as forming conductive feature 212 within trench 211, other features are contemplated as being formed by process 100. For example, dielectric features such as isolation features (e.g., shallow trench isolation structures and/or deep trench isolation structures) may be formed using the process disclosed herein. That is, the improved adhesion between the patterned photoresist layer and the underlying material layer as described herein may be used across any semiconductor processing steps that may benefit from reducing and/or preventing photoresist toppling issues during the formation of a given feature.

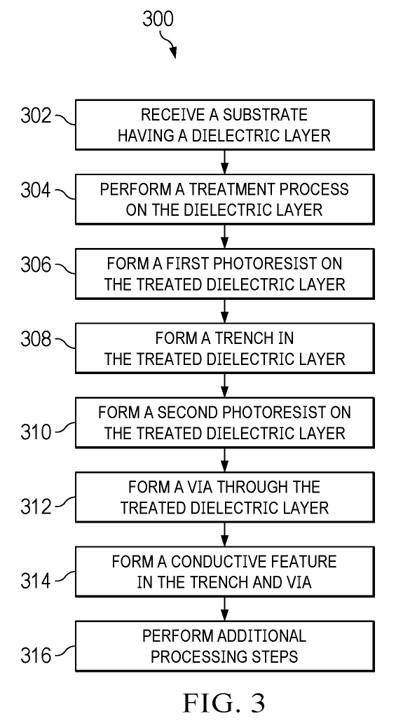

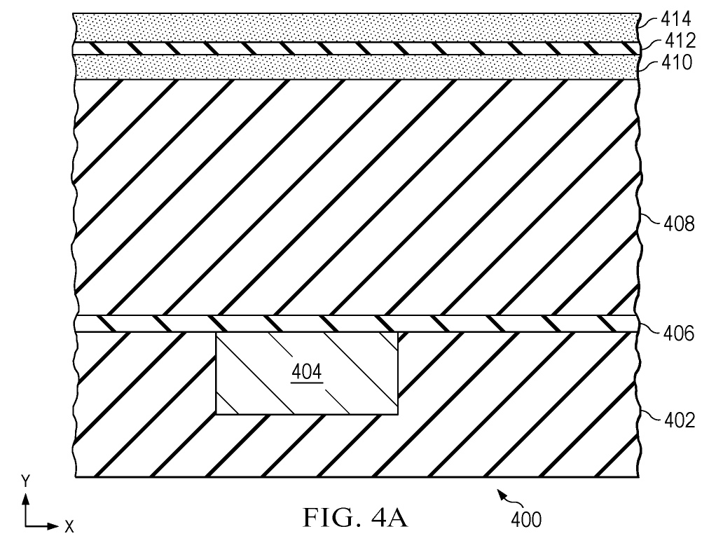

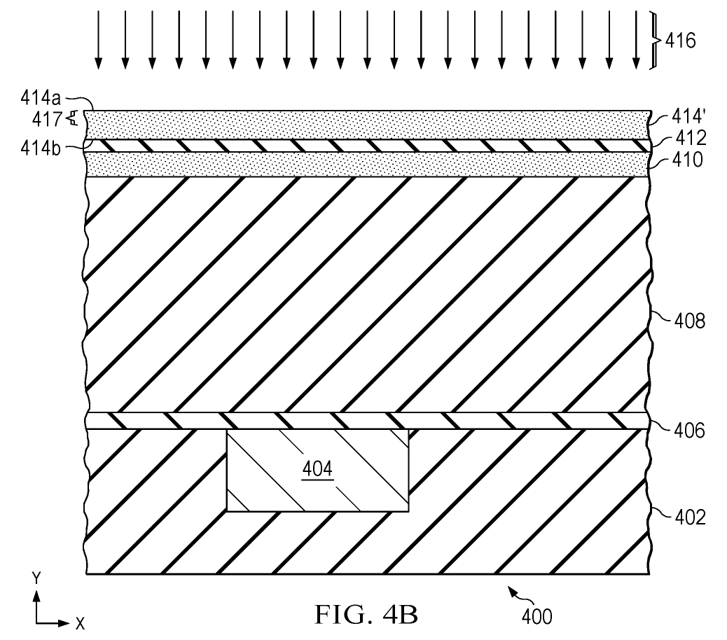

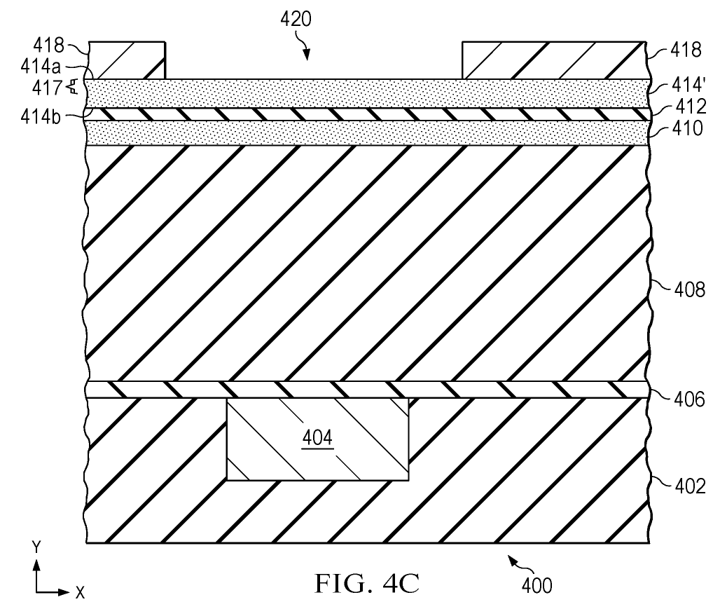

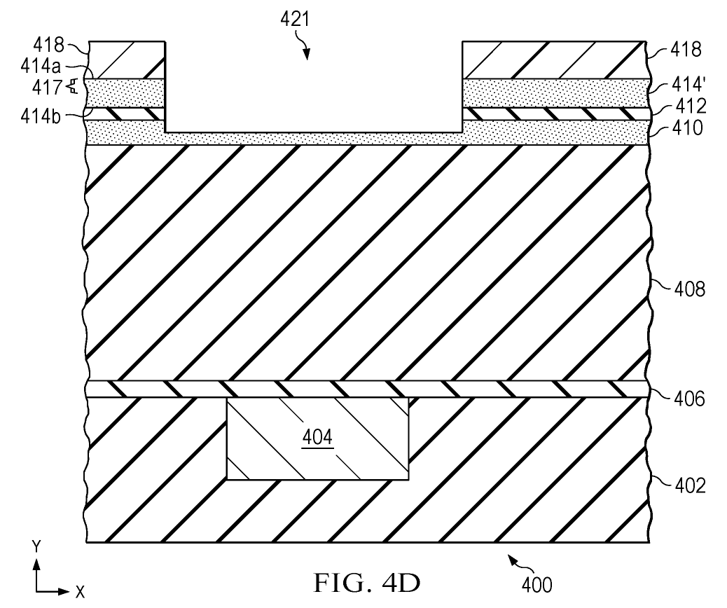

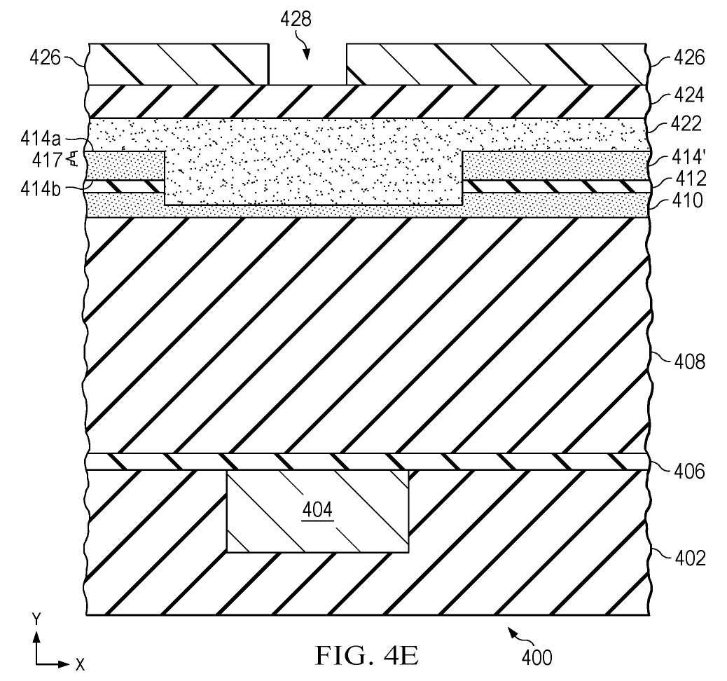

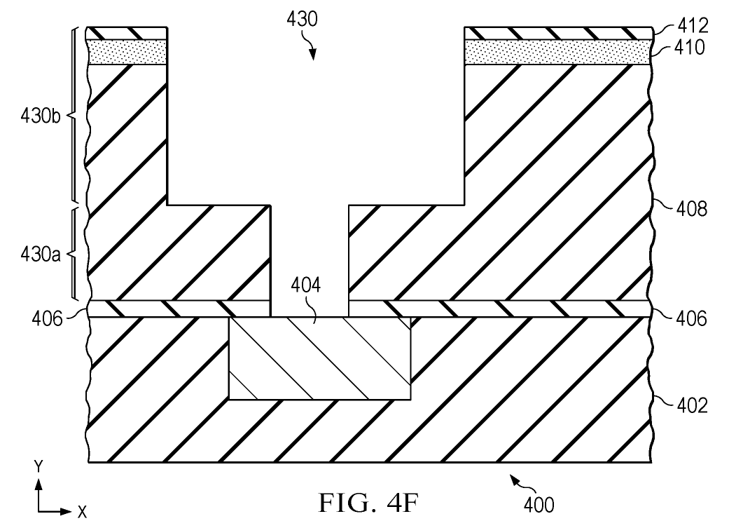

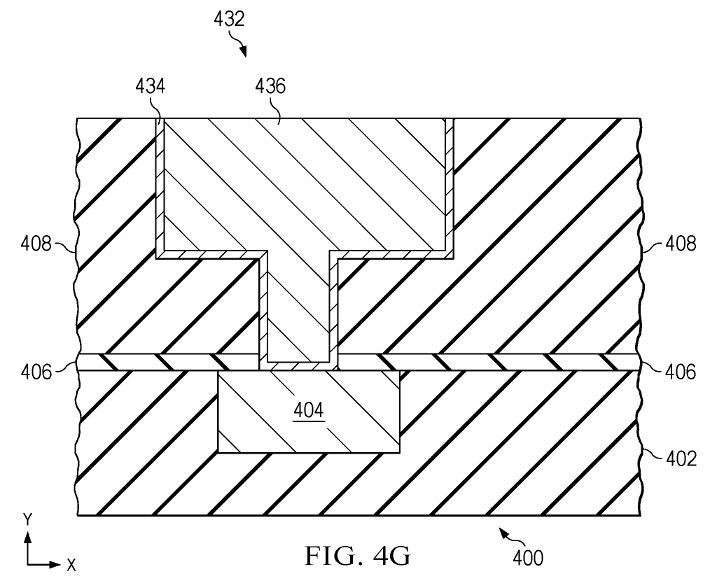

Referring now to FIG. 3, a flow diagram of a method 300 for forming an interconnect structure over a semiconductor device (e.g., a field effect transistor (FET)) in accordance with various examples of the present disclosure. In various examples, method 300 may be used to form a treated dielectric layer that improves the adhesion of a patterned photoresist layer to the treated dielectric layer. The improved adhesion of the patterned photoresist layer tends to prevent toppling of the patterned photoresist layer and thereby improve formation of the interconnect structure over the semiconductor device. Additional processes can be provided before, during, and after method 300. Various aspects of method 300 may be the same as method 100 described above and therefore may not be repeated below. As discussed below, method 300 is described with reference to FIGS. 4A-4G.

In that regard, FIGS. 4A-4G are diagrammatic cross-sectional views of a device 400 at various stages of fabrication (such as those associated with method 300 of FIG. 3) according to various aspects of the present disclosure. In various examples, device 400 may be a FET, a metal oxide semiconductor FET (MOSFET), a bipolar junction transistor (BJT), other semiconductor components, or the like. Additional features can be added to device 400, and some features described below can be replaced, modified, or eliminated in other examples of device 400. Various aspects of device 400 may be the same as device 200 and may not be repeated below.

At step 302 of FIG. 3, a substrate having a dielectric layer is received. As shown in FIG. 4A, device 400 includes a first dielectric layer 402, a first conductive feature 404, a first etch stop layer 406, a second dielectric layer 408, a second etch stop layer 410, a first hard mask layer 412, and an anti-reflective coating layer 414 (ARC layer 414). First dielectric layer 402 (or first interlayer dielectric layer) may be formed over a substrate similar to first dielectric layer 202 described above in FIG. 2A.

First conductive feature 404 is disposed within first dielectric layer 402. In some examples, first conductive feature 404 may be a metal line, via, or contact. In various examples, first conductive feature 404 may connect to one or more source/drain contacts, gate contacts, and/or other conductive features that are disposed over or in a substrate. In various examples, a trench is formed in first dielectric layer 402 and first conductive feature 404 is then formed in the trench. In various examples, the trench may be formed in first dielectric layer 402 using one or more etching processes. First conductive feature 404 may each include (i) one or more metal-barrier and/or adhesion layers (e.g., titanium (Ti), titanium nitride (TiN), tantalum (Ta), tantalum nitride (TaN), the like, or a combination thereof) conformally in a respective trench in first dielectric layer 402 and (ii) a metal (e.g., tungsten (W), copper (Cu), silver (Ag), gold (Au), aluminum (Al), the like, or a combination thereof) over and/or on the metal-barrier and/or adhesion layer(s). In some examples, the formation of first conductive feature 404 (e.g., a trench is formed in first dielectric layer 402 and first conductive feature 404 is then formed in the trench) may be performed by the processes disclosed herein including method 100 described above.

First etch stop layer 406 (or dielectric layer) is formed over first dielectric layer 402 and first conductive feature 404. In various examples, first etch stop layer 406 may include silicon nitride (SiN), silicon dioxide (SiO₂), silicon carbon nitride (SiCN), aluminum oxide (AlO), silicon carbide (SiC), the like, or any combination thereof. In various examples, first etch stop layer 406 may be formed of one or more layers. First etch stop layer 406 may be formed using one or more processes. In various examples, the one or more processes may include chemical vapor deposition (CVD), atomic layer deposition (ALD), physical vapor deposition (PVD), the like, or any combination thereof.

Second dielectric layer 408 (or second interlayer dielectric layer) is formed over first etch stop layer 406. Second dielectric layer 408 may be formed similar to first dielectric layer 402 and first dielectric layer 202 described above in FIG. 2A. In various examples, second dielectric layer 408 may include similar materials as first dielectric layer 402. In various examples, second dielectric layer 408 may include different materials than first dielectric layer 402.

Second etch stop layer 410 is formed over second dielectric layer 408. In various examples, second etch stop layer 410 may include or be silicon oxynitride (SiON). In various other examples, second etch stop layer 410 may be a dielectric material and include or be silicon dioxide, silicon nitride, a silicon oxide-based material (such as a phosphosilicate glass (PSG) or a tetraethyl orthosilicate (TEOS) oxide), polytetrafluoroethylene, low-k dielectric layers, any other dielectric material, or any combination thereof.

First hard mask layer 412 is formed over second etch stop layer 410. In various examples, first hard mask layer 412 may include a metal, a metal alloy, or a combination thereof. In various examples, first hard mask layer 412 may include titanium (Ti), titanium nitride (TiN), tantalum (Ta), tantalum nitride (TaN), the like, or a combination thereof.

ARC layer 414 (e.g., a dielectric layer) is formed over first hard mask layer 412. In various examples, ARC layer 414 may include or be a dielectric material. In various examples, ARC layer 414 may include or be silicon oxynitride (SiON). In various examples, ARC layer 414 may include the same materials as second etch stop layer 410, second dielectric layer 408, and/or first dielectric layer 402. In various examples, ARC layer 414 may include different materials than one or more of second etch stop layer 410, second dielectric layer 408, and/or first dielectric layer 402. In various examples, ARC layer 414 may be formed similar to second dielectric layer 204 described above in FIG. 2A. For purposes of clarity, the below processing steps will be described in reference to ARC layer 414 including or being a SiON material layer. However, the processing steps below are applicable to other processes where ARC layer 414 may include other oxide and/or nitride material layers.

In some examples, ARC layer 414 has a first oxygen concentration, a first nitrogen concentration, a first silicon concentration, and a first hydrogen concentration as a result of the process used to form ARC layer 414 as described above (see FIG. 2A discussion of second dielectric layer 204). In various examples, the first oxygen concentration may be about 64% to about 68%, and more specifically, about 65% to about 67%. In various examples, the first nitrogen concentration may be about 5% to about 9%, and more specifically, about 6% to about 8%. In various examples, the first silicon concentration may be about 24% to about 31%, and more specifically, about 26% to about 28%. In various examples, ARC layer 414 may be about 200 Å to about 400 Å, and more specifically, about 250 Å to about 350 Å. In various examples, the thickness of ARC layer 414 may be smaller or larger depending on process flows of other steps in manufacturing device 200. Regardless, ARC layer 414 should be sufficiently thick for a subsequent treatment process to modify ARC layer 414, as will be described below. In various examples, the first oxygen concentration may be generally uniform throughout the thickness of ARC layer 414.

At step 304 of FIG. 3, a treatment process is performed on the dielectric layer. As shown in FIG. 4B, a treatment process 416 is performed to from a treated ARC layer 414’. In various examples, treatment process 416, may also referred to as a surface treatment process, an in-situ treatment process, a nitrogen-containing treatment process, an oxygen-containing treatment, and/or an N₂O treatment process. In various examples, treatment process 416 may be performed in-situ after forming ARC layer 414. That is, treatment process 416 may be performed in the same chamber and/or tool that was used to form ARC layer 414 (e.g., without breaking vacuum of the environment). In other examples, treatment process 416 may be performed ex-situ after forming ARC layer 414. That is, treatment process 416 may be removed from the chamber and/or tool that was used to form ARC layer 414 (e.g., breaking vacuum of the environment). As described above, PECVD processes may be used to form ARC layer 414 and perform treatment process 416.

In various examples, treatment process 416 replaces nitrogen (N₂) and hydrogen (H₂) in treated ARC layer 414’ with oxygen (O₂). Additionally, treatment process 416 terminates dangling bonds (e.g., dangling Si bonds) in treated ARC layer 414’ with oxygen. As a result of terminating dangling bonds, the moisture absorption rate of treated ARC layer 414’ is less than the moisture absorption rate of ARC layer 414. As used herein, dangling Si bonds include Si molecules that have an open bond that is not occupied by another atom such as one of an oxygen, hydrogen or nitrogen atom.

As a result of treatment process 416, treated ARC layer 414’ has a second oxygen concentration, a second nitrogen concentration, a second silicon concentration, and a second hydrogen concentration. Second oxygen concentration is greater than the first oxygen concentration while second nitrogen concentration, second silicon concentration, and second hydrogen concentration are less than first nitrogen concentration, first silicon concentration, and first hydrogen concentration, respectively.

In various examples, the second oxygen concentration may be about 69% to about 73%, and more specifically, about 70% to about 72%. In various examples, second nitrogen concentration may be about 1% to about 5%, and more specifically, about 2.5% to about 4.5%. In various examples, second silicon concentration may be about 22% to about 32%, and more specifically, about 24% to about 26%. In other words, treatment process 416 may increase the oxygen concentration while decreasing the nitrogen concentration and the hydrogen concentration in portions of ARC layer 414 to form treated ARC layer 414’. In various examples, the treatment process 416 (e.g., decreasing nitrogen and/or hydrogen contents) results in treated ARC layer 414’ being denser than ARC layer 414.

In various examples, the second oxygen concentration of treated ARC layer 414’ may be a non-linear gradient with a top surface 414a (e.g., in the positive y-direction) of treated ARC layer 414’ having the highest (or higher) oxygen concentration relative to other portions of treated ARC layer 414’. As shown in FIG. 4B, top surface 414a, or treated surface, faces away from second dielectric layer 408 while an opposing bottom surface 414b of treated ARC layer 414’ faces second dielectric layer 408.

In various examples, only an upper portion 417 (e.g., in the positive y-direction) of treated ARC layer 414’ (e.g., thickness of about 10 Å to about 50 Å, and more specifically, about 20 Å to about 40 Å of second dielectric layer 204) may be affected by treatment process 416. As a result, in some examples, there may remain portions of treated ARC layer 414’ having a generally uniform oxygen concentration under (e.g., in the negative y-direction) upper portion 417 which has a higher gradient oxygen concentration. In some examples, the oxygen concentration in upper portion 417 has a linear or non-linear oxygen concentration gradient that generally increases in the positive y-direction toward top surface 414a. In some examples, a thin oxide layer is formed on top surface 414a as a result of treatment process 416.

In various examples, treatment process 416 may use nitrous oxide (N₂O), radio frequency (RF) power, and pressure to increase the oxygen (O₂) concentration (while decreasing nitrogen and/or hydrogen concentration) of treated ARC layer 414’. In some examples, the N₂O may breakdown easily with low RF power to provide a source of O₂ for treatment process 416. The temperature and pressure of treatment process 416 may cause the oxygen to replace hydrogen (H₂) and/or nitrogen (N₂) bonds in ARC layer 414 resulting in a higher oxygen concentration and a lower hydrogen and nitrogen concentration in treated ARC layer 414’. In other words, treatment process 416 reduces Si-H bonds in ARC layer 414 by replacing the H₂ in a portion of the Si-H bonds with oxygen. The increased oxygen concentration (in conjunction with decreased nitrogen and/or hydrogen concentrations) tends to increase the quality and robustness of treated ARC layer 414’ as compared to ARC layer 414. The improved quality improves the adhesion of subsequently formed photoresist layer (e.g., first patterned photoresist layer 418 described below) to treated ARC layer 414’ as compared to ARC layer 414. Accordingly, in some examples, treated ARC layer 414’ has an increased oxygen (O₂) concentration, a decreased nitrogen (N₂) concentration, a decreased hydrogen (H₂) concentration, and a lower number of dangling Si bonds than ARC layer 414, all of which improve the bonding of a photoresist layer (e.g., first patterned photoresist layer 418) to treated ARC layer 414’ as compared to ARC layer 414.

In various examples, treatment process 416 may use nitrous oxide (N₂O) and a noble gas. In various examples, the noble gas may include or be helium (He), neon (Ne), argon (Ar), xenon (Xe), radon (Rn), or the like. In various examples, one or both N₂O and the noble gas may be present from the previous PECVD process. During treatment process 416, the flow rate of N₂O may about 3,000 sccm to about 8,000 sccm, and more specifically, about 4,500 sccm to about 6,500 sccm. In examples where the noble gas is He, the flow rate of He during treatment process 416 may be about 500 sccm to about 2,500 sccm, and more specifically, about 1,000 sccm to about 2,000 sccm. Treatment process 416 may use a radio frequency (RF) power of about 250 W to about 850 W, and more specifically, about 450 W to about 650 W. The pressure of the PECVD process may be about 4 Torr to about 12 Torr, and more specifically, about 6 Torr to about 8 Torr. Treatment process 416 may performed for about 30 s to about 120 s, and more specifically, about 45 s to about 75 s.

At step 306 of FIG. 3, a first photoresist is formed on the treated dielectric layer. As shown in FIG. 4C, a first patterned photoresist layer 418 is formed on treated ARC layer 414’. First patterned photoresist layer 418 includes a first opening 420 that exposes treated ARC layer 414’. First patterned photoresist layer 418 may be formed similar to patterned photoresist layer 208 described above in FIG. 2C.

As described above, the adhesion of first patterned photoresist layer 418 to treated ARC layer 414’ is improved as compared to ARC layer 414 as a result of treatment process 416. For example, treatment process 416 may minimize (or reduce) dangling bonds (e.g., dangling Si bonds) in treated ARC layer 414’. Dangling bonds, may absorb, or capture, moisture (e.g., from the ambient, from a photoresist layer) which may cause toppling of a portion of the photoresist layer. Terminating the dangling bonds (e.g., reducing the number of dangling bonds) by bonding oxygen to the dangling Si bonds during treatment process 416 reduces the moisture absorption rate of treated ARC layer 414’. As such, ARC layer 414’ has improved adhesion properties which reduces, or prevents, toppling of first patterned photoresist layer 418. As a result, as shown in FIG. 4C, photo resist layer 418 has not experienced any toppling issues that would affect the formation of first opening 420 and/or the formation of subsequent openings, trenches, and/or other features.

At step 308 of FIG. 3, a trench is formed in the treated dielectric layer. As shown in FIG. 4D, an extended first opening 421 is formed through treated ARC layer 414’, first hard mask layer 412, and into second etch stop layer 410 using first patterned photoresist layer 418 as a mask. Extended first opening 421 may be formed using one or more etching processes. In various examples, a first etching process may be performed to etch through treated ARC layer 414’, a second etching process may be performed to etch through first hard mask layer 412, and a third etching process may be performed to etch into second etch stop layer 410. In various examples, the first etching process and the third etching process may be similar. In various examples, more or fewer etching processes may be used to form extended first opening 421. After forming extended first opening 421, first patterned photoresist layer 418 may be removed such as by an ashing process. As shown in FIG. 4D, no portion of patterned photoresist layer 418 has “toppled” over thereby blocking and/or negatively affecting the formation of extended first opening 421 while using patterned photoresist layer 418 as a mask.

At step 310 of FIG. 3, a second photoresist is formed on the treated dielectric layer. As shown in FIG. 4E, an underlayer 422, a second hard mask layer 424, and a second patterned photoresist layer 426 having a second opening 428 are formed over treated ARC layer 414’ and in extended first opening 421. In various examples, underlayer 422, second hard mask layer 424, and second patterned photoresist layer 426 may be referred to as a multi-layer resist (MLR) and be part of a trench first metal hard mask integration process. That is, underlayer 422 may be used to provide a planar surface upon which to form second hard mask layer 424 and second patterned photoresist layer 426. Underlayer 422 may be formed over treated ARC layer 414’ including in extended first opening 421.

In various examples, underlayer 422 may include an organic material. In various examples, underlayer 422 may include silicon oxide, silicon nitride, silicon oxynitride, the like, or a combination thereof. Second hard mask layer 424 may be formed over underlayer 422. In various examples, second hard mask layer 424 may include silicon oxide, silicon nitride, titanium nitride, amorphous carbon, the like, or a combination thereof. In various examples, second hard mask layer 424 may include or be a spin on glass material. Second patterned photoresist layer 426 including second opening 428 may be formed over second hard mask layer 424. Second patterned photoresist layer 426 may be formed similar to first patterned photoresist layer 418 described above, including etching to form second opening 428.

At step 312 of FIG. 3, a via is formed through the treated dielectric layer. As shown in FIG. 4F, a first trench 430 is formed through second etch stop layer 410, second dielectric layer 408, and first etch stop layer 406 using second patterned photoresist layer 426 as a mask to expose first conductive feature 404. In various examples, the lower portion of first trench 430 may be referred to as a via 430a while the upper portion may be referred to as a trench 430b. In various examples, steps 310 and 312 used to form first trench 430 may be part of a dual damascene process. Additionally, in various examples, while method 300 may be considered as part of a dual damascene process using a trench first approach it is contemplated that the methods described herein are applicable to other types of dual damascene processes including a via first approach.

After forming first trench 430, second patterned photoresist layer 426, second hard mask layer 424, underlayer 422, and treated ARC layer 414’ are removed using one or more processes. In various examples, the one or more processes may include a wet etch, a dry etch, a chemical mechanical polish (CMP) process, the like, or a combination thereof. In various examples, a different process may be used to remove each of second patterned photoresist layer 426, second hard mask layer 424, underlayer 422, and treated ARC layer 414’. In various examples, the same process may be used to remove multiple of second patterned photoresist layer 426, second hard mask layer 424, underlayer 422, and/or treated ARC layer 414’.

At step 314 of FIG. 3, a conductive feature is formed in the trench and via. As shown in FIG. 4G, a second conductive feature 432 is formed in first trench 430. Second conductive feature 432 includes a barrier layer 434 and a conductive layer 436. Second conductive feature 432 may be formed similar to conductive feature 212 described above in FIG. 2E. For example, barrier layer 434 may include similar materials and be formed similar to barrier layer 214 as described above. Furthermore, conductive layer 436 may include similar materials and be formed similar to conductive layer 216 described above. Additionally, the formation of second conductive feature 432 may include one or more processing steps that remove first hard mask layer 412 and second etch stop layer 410. In various examples, the one or more processing steps may include a wet etch, a dry etch, a chemical mechanical polish (CMP) process, the like, or a combination thereof to remove first hard mask layer 412 and second etch stop layer 410.

At step 316 of FIG. 3, additional processing steps are performed. For example, additional materials may be formed on and over device 400, including dielectric materials, contacts, interconnects, and the like. Also, for example, additional process steps may occur before, during or after method 300.

Accordingly, method 300 provides a treatment process to improve adhesion between a dielectric layer and a photoresist layer. In various examples, the dielectric layer may include oxygen and/or nitrogen (e.g., SiON), and the treatment process may include an oxygen source (e.g., nitrous oxide (N₂O)). In various examples, the treatment process may increase the oxygen concentration (while decreasing the nitrogen and hydrogen concentration) in at least a portion (e.g., upper surface) of the dielectric layer which improves the adhesion of the photoresist layer to the dielectric layer. The improved adhesion has the effect of reducing, or preventing, toppled photoresist during the steps of method 300. Reducing, or preventing, toppled photoresist improves the formation of conductive features (e.g., metal lines, vias, etc.) in the subsequently formed trench (e.g., first trench 430) and, as a result, the quality of device 400.

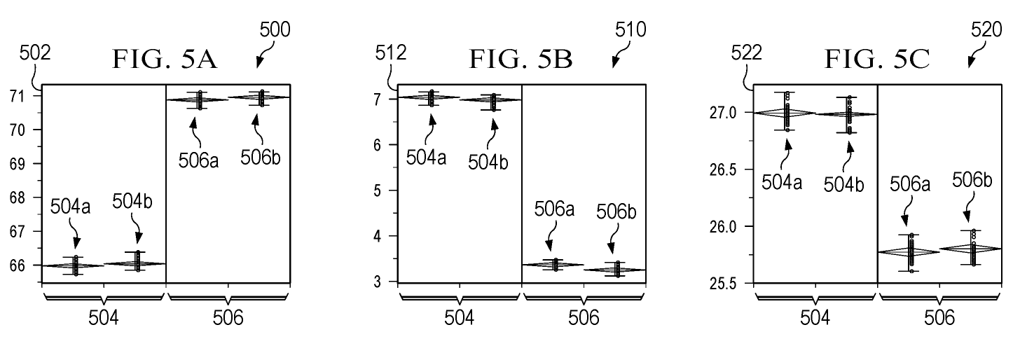

Referring now to FIGS. 5A-5C, a first chart 500, a second chart 510, and a third chart 520 show X-ray photoelectron spectroscopy (XPS) analysis of an untreated layer (e.g., second dielectric layer 204, ARC layer 414) formed using a baseline process and a treated layer (e.g., treated second dielectric layer 204’, treated ARC layer 414’) formed as a result of the methods disclosed herein. In each of first chart 500, second chart 510, and third chart 520 the y-axis represents oxygen concentration 502, nitrogen concentration 512 and silicon concentration 522, respectively. That is, the respective concentrations of oxygen, nitrogen and silicon in each chart increases in the positive y-direction. The various examples are shown along the x-axis with each chart 500, 510, and 520 showing an untreated layer 504 of a first sample 504a and a second sample 504b and a treated layer 506 of a third sample 506a and a fourth sample 506b. For ease of discussion below, first sample 504a and second sample 504b will be referred to collectively as untreated layer 504 and third sample 506a and fourth sample 506b will be referred to collectively as treated layer 506.

With respect to first chart 500 of FIG. 5A, oxygen (O₂) concentration 502 (e.g., along the y-axis) varies between untreated layer 504 and treated layer 506. As shown in first chart 500, the concentration of O₂ in treated layer 506 is greater than the concentration of O₂ of untreated layer 504. For example, oxygen concentration of untreated layer 504 is about 65.5% to about 66.5% while oxygen concentration of treated layer 506 is about 70.5% to about 71.5%. As described above, nitrogen and hydrogen atoms that were bonded with Si in untreated layer 504 are replaced with oxygen bonded to Si in treated layer 506 as a result of the treatment process disclosed herein (e.g., treatment process 206, treatment process 416). As shown, this results in treated layer 506 having a higher concentration of oxygen than untreated layer 504.

With respect to second chart 510 of FIG. 5B, nitrogen (N₂) concentration 512 (e.g., along the y-axis) varies between untreated layer 504 and treated layer 506. As shown in second chart 510, the concentration of N₂ in treated layer 506 is less than the concentration of N₂ in untreated layer 504. For example, nitrogen concentration of untreated layer 504 is about 6.5% to about 7.5% while nitrogen concentration of treated layer 506 is about 3.0% to about 4.0%. As described above, nitrogen and hydrogen atoms that were bonded with Si in untreated layer 504 are replaced with oxygen bonded to Si in treated layer 506 as a result of the treatment process disclosed herein (e.g., treatment process 206, treatment process 416). As shown, this results in treated layer 506 having a lower concentration of nitrogen than untreated layer 504.

With respect to third chart 520 of FIG. 5C, silicon (Si) concentration 522 (e.g., along the y-axis) varies between untreated layer 504 and treated layer 506. As shown in third chart 520, the concentration of Si in treated layer 506 is less than the concentration of Si in untreated layer 504. For example, silicon concentration of untreated layer 504 is about 26.75% to about 27.25% while silicon concentration of treated layer 506 is about 25.5% to about 26%. In various examples, the reduction in concentration of Si may be caused by oxidation of the Si during the treatment process.

Accordingly, the methods described herein perform a treatment process on a dielectric layer to improve the adhesion of a photoresist layer to the treated dielectric layer. In various examples, an oxygen-based gas (e.g., nitrous oxide (N₂O)) may be used as a source of oxygen for the treatment process. In various examples, the treatment process uses the oxygen-based gas to replace hydrogen (H₂) and/or nitrogen (N₂) in the dielectric layer with oxygen. For example, the treatment process may minimize dangling bonds (e.g., dangling Si bonds) in the treated dielectric layer. Dangling bonds, may absorb, or capture, moisture (e.g., from the ambient, from a photoresist layer) which may cause toppling of a portion of the photoresist layer. Terminating the dangling bonds by bonding oxygen to the dangling bonds (e.g., by replacing hydrogen and/or nitrogen) during the treatment process reduces the moisture absorption rate of the treated dielectric layer. As a result, the treated dielectric layer has fewer dangling bonds available to capture moisture. This may result in improved adhesion of the photoresist layer to the dielectric layer.

Disclosed herein are methods for performing a treatment process to improve adhesion between an underlying material layer and a photoresist layer formed thereover. In various examples, the improved adhesion may result in a reduction, or prevention, of photoresist toppling. Reducing photoresist toppling may lead to improved trench formation and, as a result, a reduction in manufacturing defects. In some examples, the disclosed methods may be used with semiconductor manufacturing processes such as trench and/or via formation processes and subsequently filling of the trench and/or via with one or more material layers (e.g., conductive and/or dielectric materials).

Finally, it should be understood that any of the above-described concepts can be used alone or in combination with any or all of the other above-described concepts. Although various examples have been disclosed and described, it is understood, recognized, and/or contemplated that certain modifications would come within the scope of this disclosure. Accordingly, the description is not intended to be exhaustive or to limit the principles described or illustrated herein to any precise form. Many modifications and variations are possible in light of the above teaching.

What is claimed is:

1. A method, comprising:
forming a material layer over a dielectric layer;
performing a treatment process, wherein a treated material layer is formed as a result of performing the treatment process, the treated material layer having an increased oxygen concentration compared to the material layer; and
forming a photoresist layer over the treated material layer.

2. The method of claim 1, wherein:
the material layer includes a surface having a first oxygen concentration as a result of forming the material layer; and
the treated material layer includes a treated surface as a result of performing the treatment process, the treated surface having a second oxygen concentration greater than the first oxygen concentration.

3. The method of claim 1, wherein:
the material layer includes a surface having a first hydrogen concentration as a result of forming the material layer; and
the treated material layer includes a treated surface as a result of performing the treatment process, the treated surface having a second hydrogen concentration less than the first hydrogen concentration.

4. The method of claim 1, wherein:
the material layer includes a silicon-containing surface having a first number of silicon dangling bonds as a result of forming the material layer; and
the treated material layer includes a treated silicon-containing surface as a result of performing the treatment process, the treated silicon-containing surface having a second number of silicon dangling bonds less than the first number of silicon dangling bonds.

5. The method of claim 1, wherein:
the material layer includes a surface having a first moisture absorption rate as a result of forming the material layer; and
the treated material layer includes a treated surface as a result of performing the treatment process, the treated surface having a second moisture absorption rate less than the first moisture absorption rate.

6. The method of claim 1, wherein the material layer includes silicon oxynitride.

7. The method of claim 1, wherein performing the treatment process includes applying a plasma with nitrous oxide (N₂O) to the material layer.

8. The method of claim 7, wherein hydrogen and nitrogen in the material layer are at least partially replaced with oxygen to form the treated material layer.

9. The method of claim 1, wherein:
forming the material layer over the dielectric layer occurs at a first pressure; and
performing the treatment process occurs at a second pressure that is greater than the first pressure.

10. A method, comprising:
forming a material layer over a substrate, the material layer including oxygen and nitrogen;
performing an N₂O treatment process to the material layer to form a treated material layer; and
forming a patterned photoresist layer over the treated material layer.

11. The method of claim 10, wherein:
the material layer has a first oxygen concentration and first nitrogen concentration after forming the material layer over the substrate; and
the treated material layer has a second oxygen concentration and second nitrogen concentration after performing the N₂O treatment process, the second oxygen concentration being greater than the first oxygen concentration and the second nitrogen concentration being less than the first oxygen concentration.

12. The method of claim 10, wherein performing the N₂O treatment process includes:
flowing nitrous oxide (N₂O) to a process chamber including the substrate with the material layer;
flowing a noble gas to the process chamber; and
applying an RF power to the process chamber.

13. The method of claim 12, wherein:
a first flow rate for N₂O is about 3,000 sccm to about 8,000 sccm;
a second flow rate for the noble gas is about 500 sccm to about 2,500 sccm; and
the RF power varies between about 250 W and about 850 W.

14. The method of claim 10, wherein:
the treated material layer is a treated silicon oxynitride material layer having a non-linear oxygen concentration gradient;
the patterned photoresist layer is formed directly on the treated silicon oxynitride material layer; and
oxygen concentration of the treated silicon oxynitride material layer is highest at an interface with the patterned photoresist layer.

15. A method, comprising:
forming a silicon oxynitride (SiON) layer over a hard mask, the SiON layer having a first oxygen concentration;
performing a treatment process, wherein a treated SiON layer is formed as a result of the performing the treatment process, the treated SiON layer having a second oxygen concentration greater than the first oxygen concentration; and
forming a patterned photoresist layer on the treated SiON layer.

16. The method of claim 15, wherein:
forming the SiON layer over the hard mask includes applying nitrous oxide (N₂O) at a first flow rate and at first pressure; and
performing the treatment process includes applying nitrous oxide (N₂O) at a second flow rate and a second pressure, the second flow rate being greater than the first flow rate and the second pressure being greater than the first pressure.

17. The method of claim 15, wherein performing the treatment process includes:
applying nitrous oxide (N₂O) to the SiON layer at a rate of about 3,000 sccm to about 8,000 sccm; and
applying a pressure of about 4 Torr to about 12 Torr.

18. The method of claim 17, wherein performing the treatment process further includes performing the treatment process for about 30 seconds to about 120 seconds.

19. The method of claim 18, wherein performing the treatment process further includes:
applying helium (He) at a flow rate of about 500 sccm to about 2,500 sccm; and
applying an RF power of about 250 W to about 850 W.

20. The method of claim 15, wherein performing the treatment process includes performing the treatment process without breaking vacuum of a process forming the SiON layer.
